(19) United States
(12) Patent Application Publication
(10) Pub. No.: US 2003/0133270 A1
(43) Pub. Date: Jul. 17, 2003

(54) Embedding type signal adapter for memory cards

(75) Inventors: Wen-Tsung Liu, Hsin Tien City (TW); Chia-Li Chen, Hsin Tien City (TW); Mi-Chang Chen, Hsin Tien City (TW)

Correspondence Address: BACON & THOMAS, PLLC, 625 SLATERS LANE, FOURTH FLOOR, ALEXANDRIA, VA, 22314

(73) Assignee: Carry Computer Eng. Co., Ltd., Taipei (TW)

(21) Appl. No.: 10/131,203

(22) Filed: Apr. 25, 2002

(30) Foreign Application Priority Data
Jan. 8, 2002 (CN) 091200064

(51) Int. Cl. H05K 7/00

(52) U.S. Cl. 361/728

(57) ABSTRACT

The embedding type signal adapter for various memory cards is used to allow insertion of any of a plurality memory cards therein, the memory card inserted therein is totally embedded therein without exposing to the outside, the adapter is comprised of: an electric circuit board; a socket having an insertion slot and a plurality of contact feet for insertion and discriminating of the memory card inserted; and a module for receiving the circuit board and the socket, an interface connecting pin board is allocated on a lateral side of the module, the pin board is typically provided with 50 pins; the memory cards can be inserted into the adapter respectively at different times for discriminating; a lower lid mounted on the lower side of the adapter; and an upper lid mounted on the upper side of the adapter when the electric circuit board and the socket are mounted on the module.

### BACKGROUND OF THE INVENTION

1. Field of the Invention

The present invention is related to an embedding type signal adapter for various memory cards, and especially to such an adapter which can be used to allow insertion of any of a plurality memory cards into a CF card interface (Compact Flash Card Adapter), the memory card inserted therein can be totally embedded in the CF card interface without exposing to the outside of the insertion slot.

2. Description of the Prior Art

The notable portable storage media have been developed from the original soft disks and compact disks to the flash memories principally based on the semiconductor storage technique, and have formed the modern shining storage media industry. However, large manufacturers have been continuously giving their brand-new principal storage media to combine with various information appliances or digital products such as notebooks (NB's), personal digital assistants (PDA's), electronic books (e-books), mobile phones, digital cameras (DSC's), digital walkmans (MP3) etc. In other words, the abovementioned products are requested to provide one more insertion slot (or even more than one insertion slot) within their limited spaces, in order to be benefit to portability and fluency of communication of information. By insertion of the small portable storage media, the functions of information management as well as fast copying and storing etc. for documents can be achieved. However, the volumes of the storage media have been becoming smaller and smaller, the memory capacities required however have been becoming larger and larger; at this moment that such additional insertion slots are provided on the digital products having been more and more lighter and thinner, manufacturers have to study and develop in this very direction.

Among the prior arts relating to the storage media in the markets, the most prevailing medium is the memory card for the CF (Compact Flash) card interface, it is disclosed in the year of 1994, and is the earliest one developed among the storage media now in the markets. The CF card is divided into two specifications, namely, the type I (3.3 mm) and the type II (5 mm) cards, they meet the memory card standard established by the CFA (Compact Flash Association), and have quite a many usages and are quite large in amount of use, merely all the digital products use the storage medium for such an interface.

Since disclosure of the CF card, large manufacturers sequentially disclose other storage media such as: the SD card (Secure Digital Card), MMC card (Multi-Media Card), MS Duo card (Memory Stick Duo Card) etc., while the popularized products in the markets are all storage media of the specification for the CF card; to integrate them to be commonly used with the CF card, an adapter called the CF card interface has been developed in the markets, it is mainly to remove the original built-in memory (Flash Memory) to leave an additional space to be used as a space for insertion of some other memory card. Such an adapter suited originally a card reader, a desktop computer or a notebook etc., they have a common feature, i.e., the inserted additional memory card is exposed out of the CF card adapter; in other words, such an adapter has been disclosed without taking consideration on the rapid development of digital products, in the present days, a CF card adapter having a memory card exposed is not accepted. Such a CF card adapter having a memory card exposed is not available for many kinds of digital products, for instance, a digital camera (DSC), a digital walkman (MP3) and a mobile phone etc. This is because that there is an additional gate provided near the insertion slot of each of the products for receiving a memory card; if such a CF card adapter having a memory card exposed is used, it may induce problems of being non esthetic and non practical of the digital product.

### SUMMARY OF THE INVENTION

Therefore, to solve the above stated problems and to provide more effects and objects, the present invention provides an embedding type signal adapter for various memory cards. Wherein, a CF type II card is used to make the adapter a signal adapter, the original built-in memory (Flash Memory) in the printed circuit board (PCB) is removed and is allocated on a lateral side of the CF type II card, to thereby leave an additional space for mounting a module in the same size as a memory card for insertion of some additional memory card. In this mode, any memory card can be totally embedded in the adapter, the module is designed to have a spring means to form a push in-push out type module, it is extremely convenient for inserting and taking out the memory card.

Another object of the present invention is to provide an adapter of a specification for common use, i.e., an SD/MMC card (Secure Digital/Multi-Media Card), or even an MS Duo card (Memory Stick Duo Card) can be inserted into the signal adapter to do the function of discriminating, reading and writing data etc.; meantime, the adapter has the function of “plug and play”, it is completely compatible with the specification of the CF card interface, and thereby is a very competitive and advanced invention.

Referring simultaneously to the attached table 1 and table 2, it can be known from the tables that, the problem of generality of the sizes, specifications of the electric appliances, operation circumstances as well as command codes etc. of the three kinds of cards, namely, the MS Duo card, the SD card and the MMC card, are generally identical. The inventor of the present invention endeavored to integrate and study various memory cards, and solved the technical problems after continuous study and tests finally to thereby provide an adapter of the CF card interface for common use—that is the embedding type signal adapter for various memory cards—.

TABLE 1
SPECIFICATION OF AN MS DUO CARD

| | |
|---|---|
| SIZE | 20 mm (wide) × 1.6 mm (height) × 31 mm (depth) |
| QUANTITY | 21.5 mm (wide) × 2.8 mm (height) × 50 mm (depth) |
| | (when in common use with the adapter) |
| QUALITY | 2 g/5 g (when in common use with the adapter) |
| MEMORY | 8 MB/16 MB/32 MB/64 MB |
| CAPACITY | |
| POWER | 2.7 volts-3.6 volts |
| SUPPLY (VOLTS) | |
| POWER | same as that of an MS card |
| CONSUMPTION | |
| OPERATION | −5-65° C. |
| CIRCUMSTANCE | |
| (temperature) | |
| STORAGE SPEED | 2 MB/s (max) |
| READING SPEED | 2.45 MB/s (max) |
| COMPATIBILITY | |
| WITH AN | |
| MS CARD | (yes) |

TABLE 2
COMPARISON AMONG SPECIFICATIONS OF
VARIOUS MEMORY CARDS

| | WIDE | HEIGHT | DEPTH | WEIGHT | VOLUME |
|---|---|---|---|---|---|
| | (mm) | (mm) | (mm) | (g) | (mm³) |
| MS card | 21.5 | 2.8 | 50 | 4 | 3010 |
| MS Duo card | 21.5 | 2.8 | 50 | 5 | 3010 |
| (with adapter) | | | | | |
| MS Duo card | 20 | 1.6 | 31 | 2 | 992 |
| (without adapter) | | | | | |
| SD card | 24 | 2.1 | 32 | 3 | 1612 |
| MMC card | 24 | 1.4 | 32 | 2 | 1075 |

The present invention will be apparent in its objects, features as well as advantages after reading the detailed description of the preferred example thereof in reference to the accompanying drawings.

### BRIEF DESCRIPTION OF THE DRAWINGS

FIG. 1 is a perspective view of the adapter of the present invention;

FIG. 2 is an analytic perspective view of the present invention;

FIG. 3 is a schematic perspective view showing a memory card is inserting into the adapter of the present invention;

FIG. 4 is a schematic perspective view showing the memory card in FIG. 3 has been completely inserted into the adapter of the present invention.

### DETAILED DESCRIPTION OF THE PREFERRED EXAMPLE

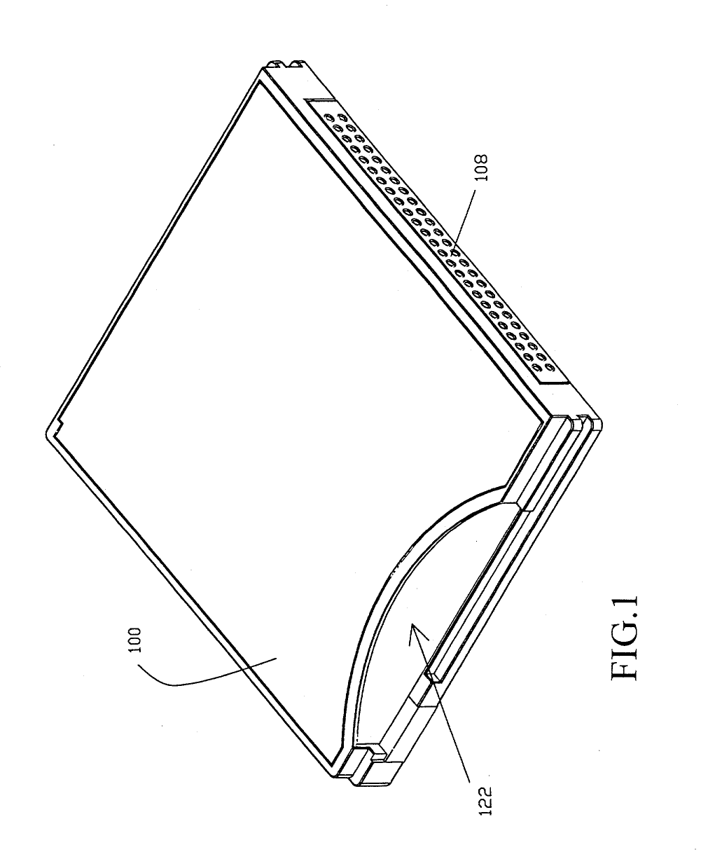

Referring to FIG. 1, there is depicted in the drawing the signal adapter 100 of the present invention. The adapter 100 of the CF card interface is a CF type II card, it not only can allow inserting therein an SD/MMC card, but also can allow the common use of it with a newly disclosed new generation memory card—MS Duo card (this is one as a sister card to an MS card). In fact, the related problems about the standards of the sizes, the electric specifications, the communication protocol, the connecting ports and command codes etc. of the adapter of the CF card interface and the memory cards (the SD/MMC/MS Duo cards etc.) are commonly known, namely, are of the specifications well known in the world, they are all for the convenience of producing related applied digital products matching therewith by downstream manufacturers. The inventor of the present invention endeavored to study and integrate various memory cards, and developed the embedding type signal adapter for various memory cards after continuous study and tests, the adapter 100 of the CF card interface can not only be commonly used for various memory cards, but also can render the memory cards totally embedded in an insertion slot 122 of the adapter 100. Apparently as shown in FIG. 1, the insertion slot 122 is allocated on any lateral side of the rectangular adapter 100; while a connecting pin board 108 of the interface is allocated on a neighboring side to that of the insertion slot 122. By this allocation, the inserted additional memory card (not shown) can totally be embedded in the adapter 100 of the present invention.

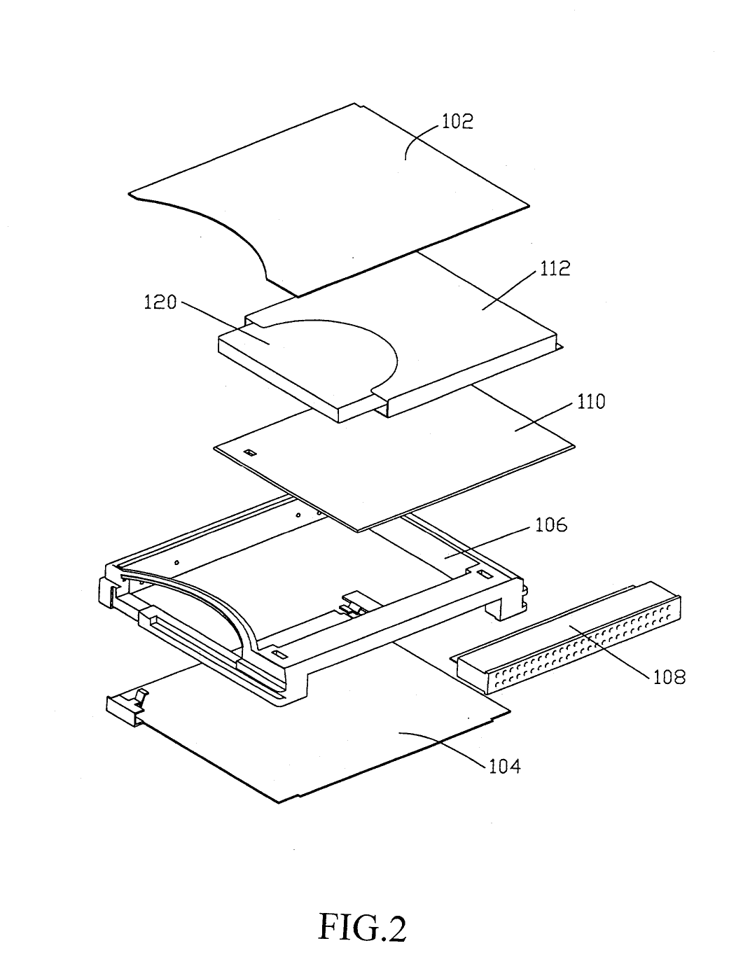

Meantime, referring to FIG. 2 which is an analytic perspective view of the present invention, wherein, the adapter 100 of the present invention is comprised at least of: an upper lid 102, a lower lid 104, a module 106, the interface connecting pin board 108, an electric circuit board 110 and a socket 112. In the electric circuit board 110 of the present invention, the original built-in memory is removed to reduce the volume of the electric circuit board 110 and to leave an additional space, thereby, the socket 112 can be mounted more deeply in the module 106. The module 106 is designed to have a spring means to form a push in-push out type module (not shown), it is extremely convenient for inserting and taking out the memory card. In other words, it is designed to render the memory card to be inserted and removed in two stages; this is convenient both for insertion and removing of the memory card. The interface connecting pin board 108 is typically provided with 50 pins, they are all electrically connected to the electric circuit board 110, and the socket 112 is electrically connected to the electric circuit board 110 too, in order to discriminate, read and write through the elements on the electric circuit board 110. However, the designing of a spring means in the module 106 and the arrangement of the electronic circuit on the electric circuit board 110 are both of conventional arts, they are not further described hereinafter.

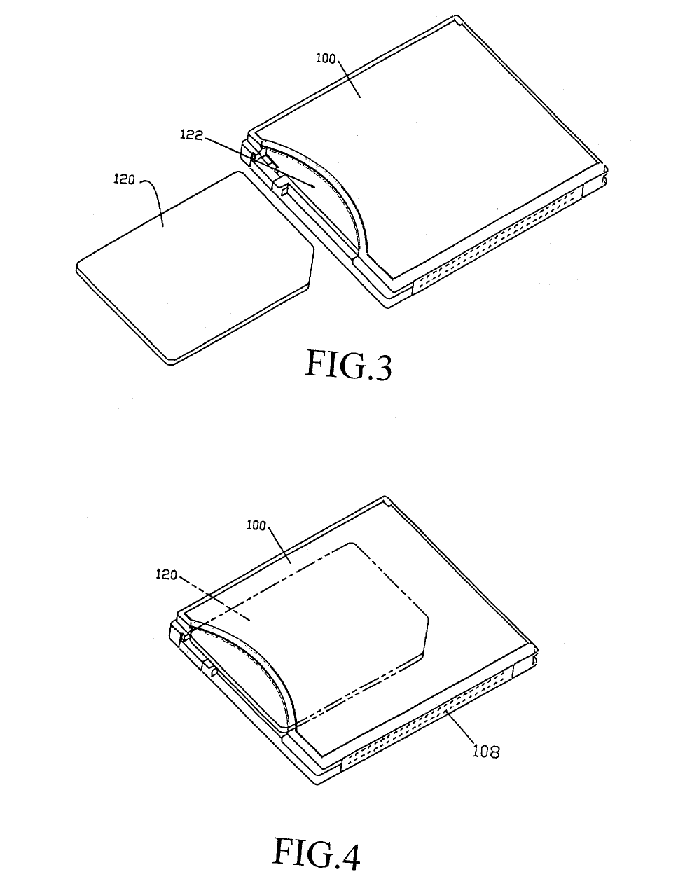

When the interface connecting pin board 108, the electric circuit board 110 and the socket 112 are respectively well allocated and positioned in the module 106 (certainly, the memory card 120 has not been inserted into the socket 112 yet), the upper and the lower lids 102, 104 are respectively mounted on the upper and the lower sides of the adapter 100. And the inner sides of the upper and the lower lids 102, 104 are stuck respectively with thermo-bond films (not shown) to thereby be insulated and separated from the module 106 to prevent short circuit. And referring to FIGS. 2, 3 in the meantime, which drawing is a schematic perspective view showing a memory card is inserting into the adapter of the present invention, the memory card 120 is depicted herein only one in number, the adapter can be inserted therein with an SD or MMC card etc., or even a newly disclosed MS Duo card. It can be seen from the above listed tables I and II that, the problem of generality of the size, specification of the electric appliance, operation circumstance as well as command code etc. of the MS Duo card are generally identical to that of an SD/MMC card. Thereby, the three kinds of memory cards 120, namely, the MS Duo card, the SD card and the MMC card, can be inserted into the socket 112 through the insertion slot 122 respectively at different times, thereby, they can be commonly used on the adapter 100 of the present invention.

Referring simultaneously to FIGS. 2, 4 which is a schematic perspective view showing the memory card in FIG. 3 has been completely inserted into the adapter of the present invention; it can be seen that the present invention is characterized by that: it provides an adapter 100 of the specification for the CF type II card interface, it has a common socket 112 to effect the functions of positioning, discriminating, reading as well as writing data. Moreover, the present invention even provides an adapter 100 to allow complete embedment of a memory card 120; in other words, the inserted memory card 120 at least can completely be flush with the edge having the inlet of the insertion slot 122 (the sizes of different memory cards 120 are different from one another) and will not be exposed out of the insertion slot 122. With such a designing, the problems of being non esthetic and non practical of the digital product such as a digital camera (DSC), a digital walkman (MP3) or a mobile phone etc. with an additional gate provided near the insertion slot thereof can be effectively solved.

The names of the members composing the present invention are only for illustrating a preferred embodiment of the present invention, and not for giving any limitation to the scope of the present invention. It will be apparent to those skilled in this art that various modifications or changes can be made to the elements of the present invention without departing from the spirit, scope and characteristic of this invention and shall fall within the scope of the appended claims and are intended to form part of this invention.

1. An embedding type signal adapter for various memory cards, said adapter is used to allow insertion of any of a plurality memory cards therein, said memory card inserted therein is totally embedded therein without exposing to the outside of said adapter, said embedding type signal adapter for various memory cards is comprised of the following elements:
an electric circuit board;
a socket provided with an insertion slot and being electrically connected to the electric circuit board in favor of insertion and discriminating of said inserted memory card; and
a module for receiving said electric circuit board and said socket, an interface connecting pin board is allocated on a lateral side of said module, said interface connecting pin board is typically provided with 50 pins; said memory cards are adapted to insertion into said adapter respectively at different times for discriminating.

2. The embedding type signal adapter as in claim 1, wherein:
said adapter is comprised of an upper lid and a lower lid respectively mounted on the upper and the lower sides of said adapter to protect said elements in the said adapter from damage.

3. The embedding type signal adapter as in claim 1, wherein:
said adapter includes a CF type II card.

4. The embedding type signal adapter as in claim 1, wherein:
said inserted memory card is an SD card.

5. The embedding type signal adapter as in claim 1, wherein:
said inserted memory card is an MMC card.

6. An embedding type signal adapter for various memory cards, said adapter is used to allow insertion of any of a plurality memory cards therein, said memory card inserted therein is totally embedded therein without exposing to the outside of said adapter, said embedding type signal adapter for various memory cards is comprised of:
an electric circuit board;
a socket provided with an insertion slot and being electrically connected to the electric circuit board in favor of insertion and discriminating of said inserted memory card; and
a module for receiving said electric circuit board and said socket, an interface connecting pin board is allocated on a lateral side of said module, said interface connecting pin board is typically provided with 50 pins; said memory cards are adapted to insertion into said adapter respectively at different times for discriminating;
a lower lid mounted on the lower side of said adapter; and
an upper lid mounted on the upper side of said adapter when said electric circuit board and said socket are mounted on said module.

7. The embedding type signal adapter as in claim 6, wherein:
said adapter includes a CF type II card.

8. The embedding type signal adapter as in claim 6, wherein:
said inserted memory card is an SD card.

9. The embedding type signal adapter as in claim 6, wherein:
said inserted memory card is an MMC card.

10. The embedding type signal adapter as in claim 6, wherein:
said inserted memory card is an MS Duo card.
